(19) United States
(12) Patent Application Publication
(10) Pub. No.: US 2019/0103274 A1
(43) Pub. Date: Apr. 4, 2019

(54) METHOD OF TRANSFERRING MICRO DEVICE

(71) Applicant: TAIFLEX Scientific Co., Ltd., Kaohsiung (TW)

(72) Inventors: Hsiu-Ming Chang, Kaohsiung (TW); Po-Wen Lin, Kaohsiung (TW); Tsung-Tai Hung, Kaohsiung (TW)

(73) Assignee: TAIFLEX Scientific Co., Ltd., KAOHSIUNG (TW)

(21) Appl. No.: 15/826,728

(22) Filed: Nov. 30, 2017

(30) Foreign Application Priority Data
Sep. 29, 2017 (TW) 106133598

(51) Int. Cl. H01L 21/263; H01L 27/15; H01L 21/67; H01L 33/00

(52) U.S. Cl. CPC H01L 21/263; H01L 27/156; H01L 33/0095; H01L 21/67144; H01L 21/67132

(57) ABSTRACT

A method of transferring micro devices is provided. A carrier substrate having a first surface and a second surface opposite to each other is provided, wherein a plurality of micro devices is disposed on the first surface, and each micro device binds to the first surface through laser debonding gel. Next, a receiving substrate is subjected to be relatively closer to the first surface, and a mask is provided on the second surface. Afterwards, the second surface with the mask is irradiated with a laser light, so as to keep the micro devices without laser irradiation binding on the first surface, and the micro devices irradiated with the laser light lose adhesive force and transfer to the receiving substrate.

### CROSS-REFERENCE TO RELATED APPLICATION

This application claims the priority benefit of Taiwan application serial no. 106133598, filed on Sep. 29, 2017. The entirety of the above-mentioned patent application is hereby incorporated by reference herein and made a part of this specification.

### BACKGROUND OF THE INVENTION

### Field of the Invention

The invention is related to a method of transferring, and more particularly, to a method of transferring micro devices.

### Description of Related Art

Having advantages such as high brightness, high contrast, wide view angle, long service life and low power consumption, micro light-emitting diode display (micro LED display) has become the key of the future development of the display technology. The technology of directly moving micro light-emitting diode (micro LED) crystals to the driver backplane is called the mass transfer process, and the mass transfer process has the following technical obstacles. First, micro LEDs have an extremely tiny size (about 5 μm to 10 μm) and require more meticulous operative skills. Besides, as hundreds of thousands or millions of micro LEDs constitute only one panel, micro LEDs in a massive number of tens to hundreds of thousands are moved in one single transfer process.

In the prior art, methods of mechanical electrostatic attraction or adhesion by adhesive tape are often used to perform mass transfer process. The attractor and robot arms of the mechanical electrostatic attraction method are rather large, and thus are incapable of attracting micro LEDs smaller than 10 μm and transferring in a massive number. The method of adhesion by adhesive tape has the shortcoming of uneven adhesive force. When removing the adhesive force, the adhesive force decreases unstably and causes yield loss. Also, as the tape has a large area, it is incapable of selecting a micro LED at a particular location.

Based on the above, it is an important research topic to develop a method of transferring a mass of micro LEDs at one time, which is also adaptable for micro LEDs of tiny sizes (10 μm or smaller) and capable of selecting a micro LED at a particular location.

### SUMMARY OF THE INVENTION

The invention provides a method of transferring micro devices which mainly uses a mask and a laser debonding gel, so as to transfer a mass of micro LEDs at one time. In addition, the method is adaptable for micro LEDs of tiny sizes (10 μm or smaller), and is further capable of selecting a micro LED at a particular location during the transfer process.

The method of transferring micro devices of the invention includes the following steps. A carrier substrate having a first surface and a second surface opposite to each other is provided, wherein a plurality of micro devices is disposed on the first surface, and each of the plurality of micro devices binds to the first surface through a laser debonding gel. Next, a receiving substrate is subjected to be relatively closer to the first surface, and a mask is provided on the second surface. Afterwards, the second surface with the mask is irradiated with a laser light, so as to keep the micro devices without laser irradiation binding on the first surface, and the micro devices irradiated with the laser light lose adhesive force and transfer to the receiving substrate.

In an embodiment of the invention, the method of transferring micro devices further includes coating the laser debonding gel on the first surface, so that each of the plurality of micro devices binds to the first surface through the laser debonding gel.

In an embodiment of the invention, the method of transferring micro devices further includes coating the laser debonding gel on each of the plurality of micro devices so that each of the plurality of micro devices binds to the first surface through the laser debonding gel in between.

In an embodiment of the invention, the plurality of micro devices disposed on the first surface is a plurality of micro LEDs emitting lights in a same color.

In an embodiment of the invention, the plurality of micro devices disposed on the first surface is a plurality of micro LEDs emitting lights in different colors.

In an embodiment of the invention, the carrier substrate is a glass substrate, and the receiving substrate is a driver integrated circuit (IC) on glass substrate.

In an embodiment of the invention, a material of the laser debonding gel includes polyimide.

In an embodiment of the invention, the laser debonding gel loses adhesive force when irradiated with a laser light having a wave length in a range from 200 mn to 1064 nm.

Based on the above, the invention provides a method of transferring micro devices includes binding the plurality of micro LEDs to a glass with the laser debonding gel and, along with the mask, keeping the plurality of micro LEDs without laser irradiation binding on the glass, and the plurality of micro LEDs irradiated with the laser light loses adhesive force and transfers to a driver backplane. As such, the method of transferring micro devices of the invention is capable of transferring a mass of micro LEDs at one time, is adaptable for micro LEDs of tiny sizes (10 μm or smaller), and is further capable of selecting a micro LED at a particular location during the transfer process.

To make the aforementioned and other features and advantages of the invention more comprehensible, several embodiments accompanied with figures are described in detail as follows.

### BRIEF DESCRIPTION OF THE DRAWINGS

The accompanying drawings are included to provide a further understanding of the disclosure, and are incorporated in and constitute a portion of this specification. The drawings illustrate exemplary embodiments of the disclosure and, together with the description, serve to explain the principles of the disclosure.

FIG. 1A to FIG. 1F are schematic cross-sectional views of a method of transferring micro devices according to the first embodiment of the invention.

FIG. 2A to FIG. 2F are schematic cross-sectional views of a method of transferring micro devices according to the second embodiment of the invention.

### DESCRIPTION OF THE EMBODIMENTS

In order to clearly illustrate the invention, the sizes and the ratios of the layers and regions may be exaggerated in the figures of the specification. In addition, the number of the devices (such as the micro devices) as illustrated is merely an example and should not be construed as a limitation to the invention. The number of the device may be adjusted according to practical operations.

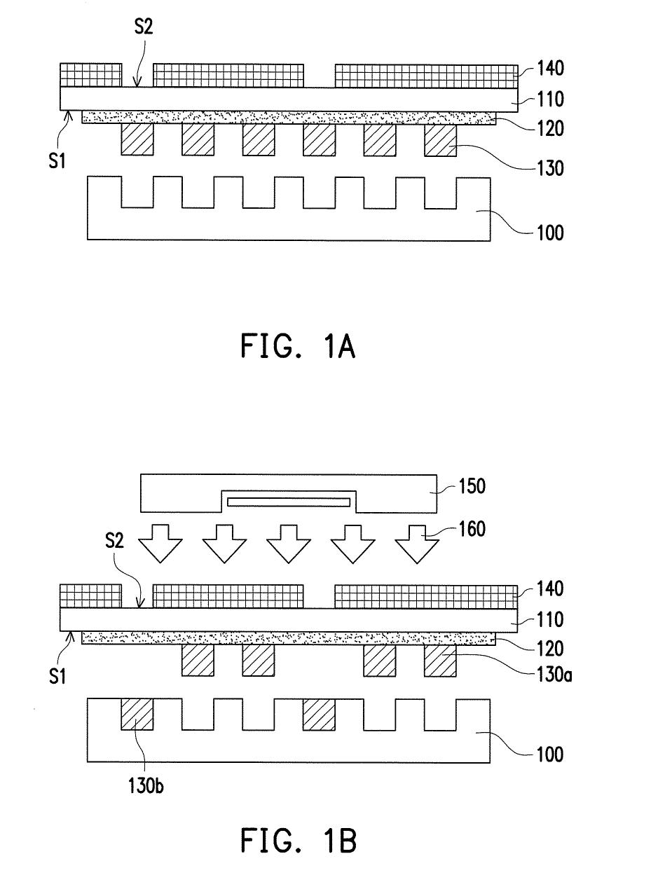

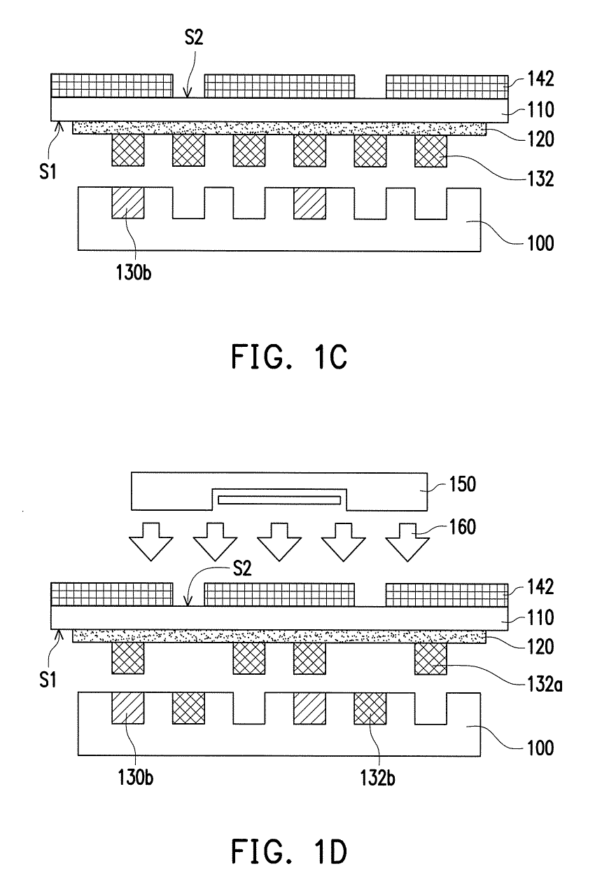

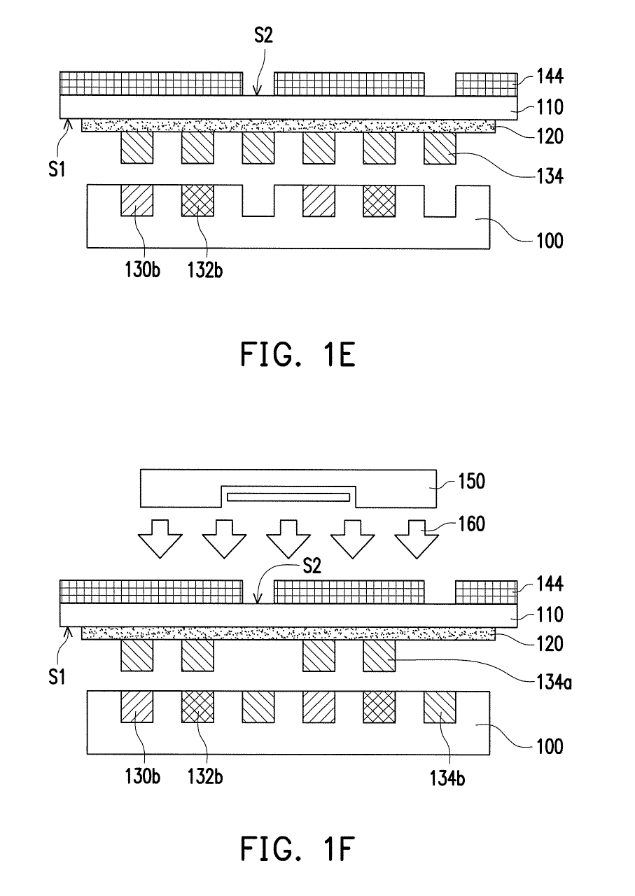

FIG. 1 A to FIG. 1F are schematic cross-sectional views of a method of transferring micro devices according to the first embodiment of the invention.

First, referring to FIG. 1A, a carrier substrate 110 having a first surface S1 and a second surface S2 opposite to each other is provided, wherein a plurality of micro devices 130 is disposed on the first surface S1, and each of the plurality of micro devices 130 binds to the first surface S1 through a laser debonding gel 120. It should be noted that, although FIG. 1A illustrates coating the laser debonding gel 120 on the first surface S1, so that each of the plurality of micro devices 130 binds to the first surface S1 through the laser debonding gel 120, the invention is not limited thereto. The laser debonding gel may be coated only on each of the plurality of micro devices 130, so that each of the plurality of micro devices 130 binds to the first surface S1 through the laser debonding gel. Also, the descriptions herein related to binding micro devices to the first surface S1 through a laser debonding gel 120 are not only adapted for the plurality of micro devices 130 but also adapted for the plurality of micro devices 132 and 134 to be mentioned in the following.

More specifically, the carrier substrate 110 is, for example, a glass substrate. A material of the laser debonding gel 120 may include polyimide, and the laser debonding gel 120 loses adhesive force when irradiated with a laser light that, for example, has a wave length in a range from 200 nm to 1064 nm, but the present invention is not limited thereto. Other laser debonding gel losing adhesive force when irradiated with a laser light may also be used. In this embodiment, the plurality of micro devices 130 disposed on the first surface S1 is a plurality of micro LEDs emitting lights in a same color, for example, red LEDs, but the invention is not limited thereto. Green or blue LEDs may also be selected according to the operation requirements.

Next, still referring to FIG. 1A, a receiving substrate 100 and the first surface S1 are subjected to be relatively closer to each other, and a mask 140 is provided on the second surface S2. More specifically, the receiving substrate 100 is, for example, a driver IC on glass substrate, and a material of the mask 140 is, for example, quartz glass or plastic. In FIG. 1A, the mask 140 is directly disposed on the second surface S2 of the carrier substrate 110 and contacts the second surface S2, but the invention is not limited thereto. The mask 140 may also be in a distance from the second surface S2 of the carrier substrate 110 and does not contact the second surface S2. Also, the descriptions herein related to providing a mask are not only adapted for the mask 140 but also adapted for the mask 142, 144, 240, 242 and 244 to be mentioned in the following.

Afterwards, referring to FIG. 1B, the second surface S2 with the mask 140 is irradiated with a laser light 160 introduced by a laser apparatus 150, so as to keep a plurality of micro devices 130a without laser irradiation binding on the first surface S1, and a plurality of micro devices 130b irradiated with the laser light 160 loses adhesive force and transfers to the receiving substrate 100. In detail, the laser light 160 has a wavelength of, for example, 355 nm, and the laser debonding gel may lose adhesive force when irradiated with a laser light that, for example, has a wave length of 355 nm. When the second surface S2 with the mask 140 is irradiated with the laser light 160, a space corresponding to an opening of the mask 140, where the plurality of micro devices 130b is located, is left uncovered and irradiated with the laser light 160. Thus, a portion of the laser debonding gel 120 between the plurality of micro devices 130b and the first surface S1 loses adhesive force, resulting the plurality of micro devices 130b to fall and transfer to the receiving substrate 100. On the other hand, a space covered by the mask 140, where the plurality of micro devices 130a is located, is not irradiated with the laser light 160. Thus, the adhesive force of a portion of the laser debonding gel 120 between the plurality of micro devices 130a and the first surface S1 is not influenced, and the plurality of micro devices 130a keeps binding on the first surface S1.

As such, the method of transferring micro devices of the invention is not only adaptable for micro LEDs of tiny sizes (10 μm or smaller), but also capable of selecting a micro LED at a particular location during the transfer process by the mask design corresponding to the micro devices intended to be debonded and transferred, so as to solve the problem of removing a malfunctioned LED.

Afterwards, referring to FIG. 1C, a plurality of micro devices 132 is disposed on the first surface S1, and each of the micro devices 132 binds to the first surface S1 through the laser debonding gel 120. In this embodiment, the plurality of micro devices 132 disposed on the first surface S1 is a plurality of micro LEDs emitting lights in a same color, for example, green LEDs, but the present invention is not limited thereto. Other LEDs emitting lights in a color different from the plurality of micro devices 130 may also be selected according to the operation requirements.

Still referring to FIG. 1C, the receiving substrate 100 having the plurality of micro devices 130b transferred thereto and the first surface S1 are subjected to be relatively closer to each other, and a mask 142 is provided on the second surface S2. A material of the mask 142 may be the same as that of the mask 140.

Afterwards, referring to FIG. 1D, the second surface S2 with the mask 142 is irradiated with a laser light 160 introduced by a laser apparatus 150, so as to keep a plurality of micro devices 132a without laser irradiation binding on the first surface S1, and a plurality of micro devices 132b irradiated with the laser light 160 loses adhesive force and transfers to the receiving substrate 100. In FIG. 1D, a technical mechanism similar to which described in the above FIG. 1B is used. By designing the location of the opening of the mask 142, a space corresponding to an opening, where the plurality of micro devices 132b is located, is left uncovered and irradiated with the laser light 160. Thus, a portion of the laser debonding gel 120 between the plurality of micro devices 132b and the first surface S1 loses adhesive force, resulting the plurality of micro devices 132b to fall and transfer to the receiving substrate 100. On the other hand, a space covered by the mask 142, where the plurality of micro devices 132a is located, is not irradiated with the laser light 160. Thus, the adhesive force of a portion of the laser debonding gel 120 between the plurality of micro devices 132a and the first surface S1 is not influenced, and the plurality of micro devices 132a keeps binding on the first surface S1.

Next, referring to FIG. 1E, a plurality of micro devices 134 is disposed on the first surface S1, and each of the micro devices 134 binds to the first surface S1 through the laser debonding gel 120. In this embodiment, the plurality of micro devices 134 disposed on the first surface S1 is a plurality of micro LEDs emitting lights in a same color, for example, blue LEDs, but the invention is not limited thereto. Other LEDs emitting lights in a color different from the plurality of micro devices 130 and 132 may also be selected according to the operation requirements.

Still referring to FIG. 1E, the receiving substrate 100 having the plurality of micro devices 130b and 132b transferred thereto and the first surface S1 are subjected to be relatively closer to each other, and a mask 144 is provided on the second surface S2. A material of the mask 144 may be the same as that of the mask 140 and 142.

Afterwards, referring to FIG. 1F, the second surface S2 with the mask 144 is irradiated with a laser light 160 introduced by a laser apparatus 150, so as to keep a plurality of micro devices 134a without irradiation of the laser light 160 binding on the first surface S1, and a plurality of micro devices 134b irradiated with the laser light 160 loses adhesive force and transfers to the receiving substrate 100. In FIG. 1F, a technical mechanism similar to which described in the above FIG. 1B is used. By designing the location of the opening of the mask 144, a space corresponding to an opening, where the plurality of micro devices 134b is located, is left uncovered and irradiated with the laser light 160. Thus, a portion of the laser debonding gel 120 between the plurality of micro devices 134b and the first surface S1 loses adhesive force, resulting the plurality of micro devices 134b to fall and transfer to the receiving substrate 100. On the other hand, a space covered by the mask 144, where the plurality of micro devices 134a is located, is not irradiated with the laser light 160. Thus, the adhesive force of a portion of the laser debonding gel 120 between the plurality of micro devices 134a and the first surface S1 is not influenced, and the plurality of micro devices 134a keeps binding on the first surface S1. As such, the transfer of micro LEDs emitting lights in different colors (red LEDs, green LEDs and blue LEDs) is accomplished.

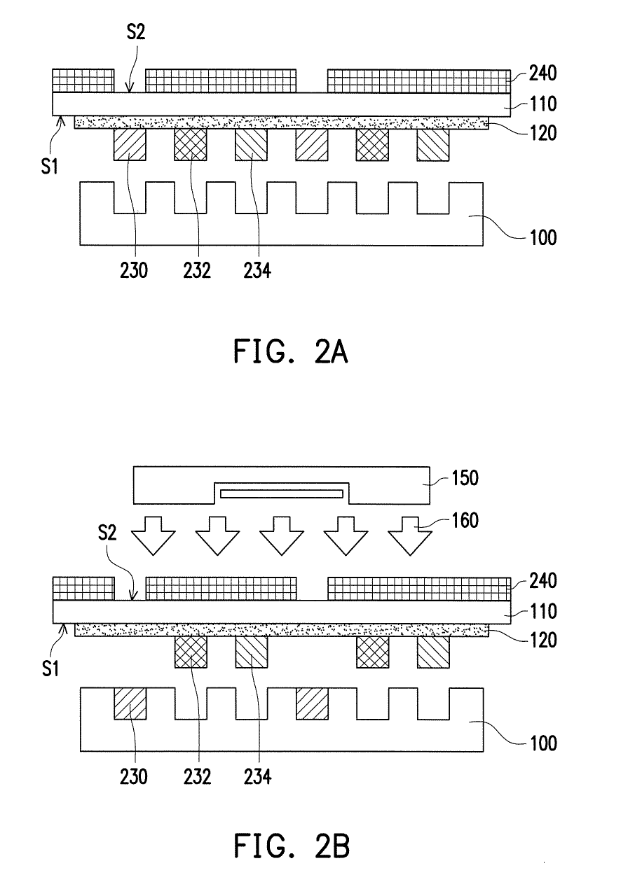

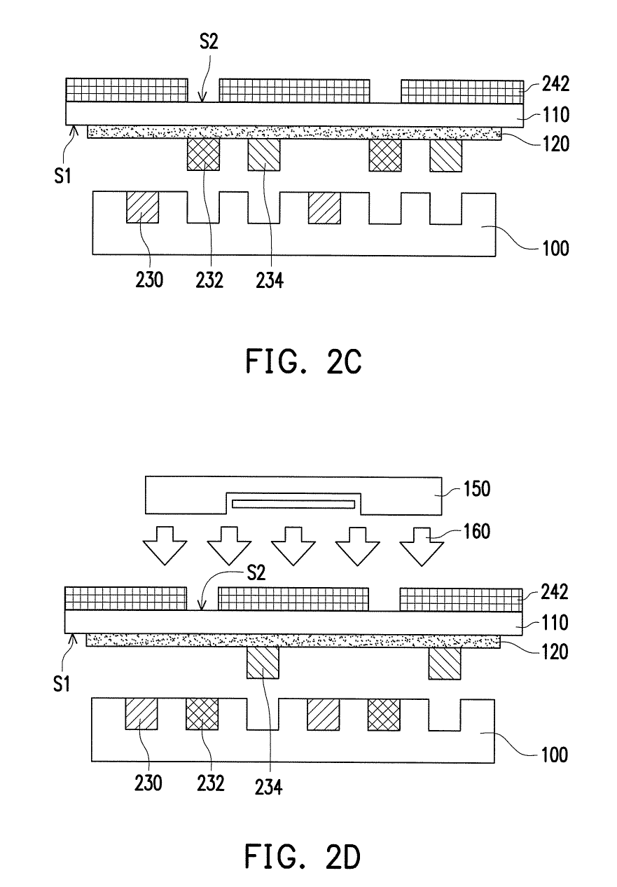

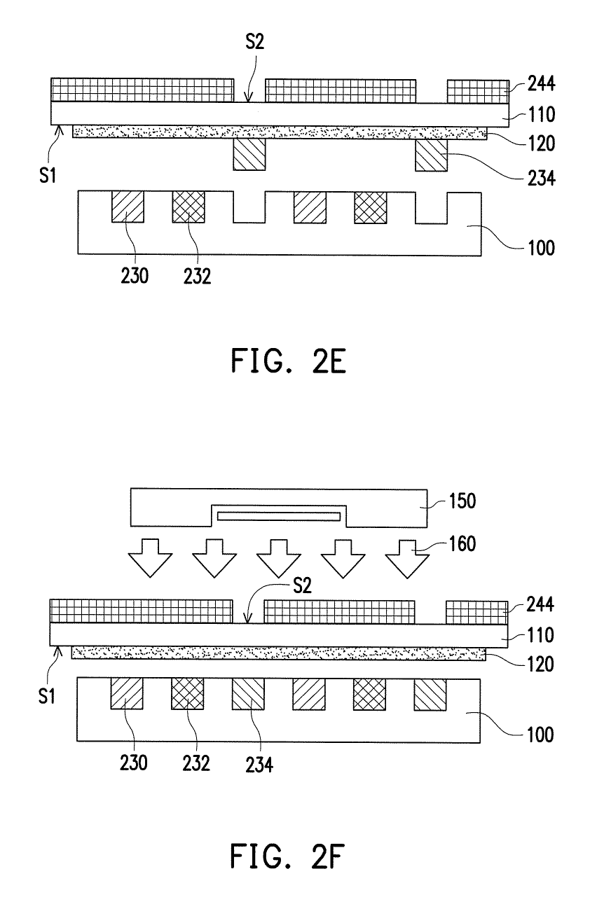

In the first embodiment as illustrated in the above FIG. 1A to FIG. 1F, the method of transferring micro devices disposes a plurality of micro LEDs emitting lights in a same color on the carrier substrate 110, but the invention is not limited thereto. A plurality of micro LEDs emitting lights in different colors may be disposed on the carrier substrate 110 according to the operation requirements, as in the second embodiment illustrated in FIG. 2A to FIG. 2F.

FIG. 2A to FIG. 2F are schematic cross-sectional views of a method of transferring micro devices according to the second embodiment of the invention. It should be noted herein that the embodiment illustrated in FIG. 2A to FIG. 2F is similar to the embodiment illustrated in FIG. 1A to FIG. 1F. Therefore, portion of the reference numerals and contents of the previous embodiment are used to describe this embodiment, wherein the same reference numerals are used to represent identical or similar elements, and description of repeated technical contents are omitted. Please refer to the description of the previous embodiment for the omitted contents, which will not be repeated hereinafter.

First, referring to FIG. 2A, a carrier substrate 110 having a first surface S1 and a second surface S2 opposite to each other is provided, wherein a plurality of micro devices 230, 232 and 234 is disposed on the first surface S1, and each of the micro devices plurality of micro devices 230, 232 and 234 binds to the first surface S1 through a laser debonding gel 120. It should be noted that, although FIG.2A illustrates coating the laser debonding gel 120 on the first surface S1, so that each of the plurality of micro devices 230, 232 and 234 binds to the first surface S1 through the laser debonding gel 120, the invention is not limited thereto. The laser debonding gel may be coated only on each of the plurality of micro devices 230, 232 and 234, so that each of the plurality of micro devices 230, 232 and 234 binds to the first surface S1 through the laser debonding gel.

In an embodiment of the invention, the plurality of micro devices 230, 232 and 234 disposed on the first surface S1 are a plurality of micro LEDs emitting lights in different colors. For example, micro devices 230 may be red LEDs, micro devices 232 may be green LEDs, and micro devices 234 may be blue LEDs. However, the invention is not limited thereto and may be adjusted according to the operation requirements.

Next, still referring to FIG. 2A, the receiving substrate 100 and the first surface S1 are subjected to be relatively closer to each other, and a mask 240 is provided on the second surface S2. A material of the mask 240 may be the same as that of the mask 140 of the aforementioned embodiment.

Afterwards, referring to FIG. 2B, the second surface S2 with the mask 240 is irradiated with a laser light 160 introduced by a laser apparatus 150, so as to keep micro devices 232 and 234 without irradiation of the laser light 160 binding on the first surface S1, and the plurality of micro devices 230 irradiated with the laser light 160 loses adhesive force and transfers to the receiving substrate 100. In FIG. 2B, a technical mechanism similar to which described in the FIG. 1B of the above embodiment is used. By designing the location of the opening of the mask 240, a space corresponding to an opening, where the plurality of micro devices 230 is located, is left uncovered and irradiated with the laser light 160. Thus, a portion of the laser debonding gel 120 between the plurality of micro devices 230 and the first surface S1 loses adhesive force, resulting micro devices 230 to fall and transfer to the receiving substrate 100. On the other hand, a space covered by the mask 240, where the micro devices 232 and 234 are located, is not irradiated with the laser light 160. Thus, the adhesive force of a portion of the laser debonding gel 120 between the micro devices 232 and 234 and the first surface S1 is not influenced, and the micro devices 232 and 234 keep binding on the first surface S1.

Next, referring to FIG. 2C, the receiving substrate 100 having the micro devices 230 transferred thereto and the first surface S1 are subjected to be relatively closer to each other, and a mask 242 is provided on the second surface S2. A material of the mask 242 may be the same as that of the mask 240.

Afterwards, referring to FIG. 2D, the second surface S2 with the mask 142 is irradiated with a laser light 160 introduced by a laser apparatus 150, so as to keep the micro devices 234 without irradiation of the laser light 160 binding on the first surface S1, and the plurality of micro devices 232 irradiated with the laser light 160 loses adhesive force and transfers to the receiving substrate 100. In FIG. 2D, a technical mechanism similar to which described in the above FIG. 2B is used. By designing the location of the opening of the mask 242, a space corresponding to an opening, where the plurality of micro devices 232 is located, is left uncovered and irradiated with the laser light 160. Thus, a portion of the laser debonding gel 120 between the micro devices 232 and the first surface S1 loses adhesive force, resulting the micro devices 232 to fall and transfer to the receiving substrate 100. On the other hand, a space covered by the mask 142, where the plurality of micro devices 234 is located, is not irradiated with the laser light 160. Thus, the adhesive force of a portion of the laser debonding gel 120 between the micro devices 234 and the first surface S1 is not influenced, and the plurality of micro devices 234 keeps binding on the first surface S1.

Then, referring to FIG. 2E, the receiving substrate 100 having the micro devices 230 and 232 transferred thereto and the first surface S1 are subjected to be relatively closer to each other, and a mask 244 is provided on the second surface S2. A material of the mask 244 may be the same as that of the mask 240 and 242.

Afterwards, referring to FIG. 2F the second surface S2 with the mask 244 is irradiated with the laser light 160 introduced by the laser apparatus 150, so that the micro devices 234 irradiated with the laser light 160 lose adhesive force and transfer to the receiving substrate 100. In FIG. 2F, a technical mechanism similar to which described in the above FIG. 2B is used. By designing the location of the opening of the mask 244, a space corresponding to an opening, where the plurality of micro devices 234 is located, is left uncovered and irradiated with the laser light 160. Thus, a portion of the laser debonding gel 120 between the micro devices 234 and the first surface S1 loses adhesive force, resulting the micro devices 234 to fall and transfer to the receiving substrate 100. As such, the transfer of micro LEDs emitting lights in different colors (red LEDs, green LEDs and blue LEDs) is accomplished.

To sum up, the method of transferring micro devices of the invention overcomes the technical obstacle of mass transfer process by using the mask and laser debonding gel, wherein the mask design corresponds to the micro devices intended to be debonded and transferred. In detail, the method of transferring micro devices of the invention is capable of transferring a mass of micro LEDs at one time, is adaptable for micro LEDs of tiny sizes (10 μm or smaller), and is further capable of selecting a micro LED at a particular location during the transfer process to solve the problem of removing a malfunctioned LED. Therefore, various shortcomings of conventional methods to perform mass transfer process, namely mechanical electrostatic attraction or adhesion by adhesive tape, are overcome.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

1. A method of transferring micro devices, comprising:
providing a carrier substrate having a first surface and a second surface opposite to each other, wherein a plurality of micro devices is disposed on the first surface, and each of the plurality of micro devices binds to the first surface through a laser debonding gel, the laser debonding gel is coated on the first surface continuously;
subjecting a receiving substrate to the first surface and providing a mask on the second surface; and
irradiating the second surface with the mask with a laser light, so as to keep the plurality of micro devices without laser irradiation binding on the first surface, and the plurality of micro devices irradiated with the laser light loses adhesive force and transfers to the receiving substrate.

2. (canceled)

3. (canceled)

4. The method of transferring micro devices according to claim 1, wherein the plurality of micro devices disposed on the first surface is a plurality of micro light-emitting diodes emitting lights in a same color.

5. The method of transferring micro devices according to claim 1, wherein the plurality of micro devices disposed on the first surface is a plurality of micro light-emitting diodes emitting lights in different colors.

6. The method of transferring micro devices according to claim 1, wherein the carrier substrate is a glass substrate, and the receiving substrate is a driver integrated circuit on glass substrate.

7. The method of transferring micro devices according to claim 1, wherein a material of the laser debonding gel comprises polyimide.

8. The method of transferring micro devices according to claim 1, wherein the laser debonding gel loses adhesive force when irradiated with a laser light having a wave length in a range from 200 nm to 1064 nm.

9. The method of transferring micro devices according to claim 1, wherein the laser debonding gel is coated on the first surface continuously at least from an edge of the leftmost micro device to an edge of the rightmost micro device.
